(19) United States
(12) Patent Application Publication
(10) Pub. No.: US 2025/0220880 A1
(43) Pub. Date: Jul. 3, 2025

(54) TRANSISTORS WITH ENHANCED ON-STATE CURRENT

(71) Applicant: Micron Technology, Inc., Boise, ID (US)

(72) Inventors: Kamal M. Karda, Boise, ID (US); Haitao Liu, Boise, ID (US); Anthony J. Kanago, Boise, ID (US); Si-Woo Lee, Saratoga, CA (US)

(21) Appl. No.: 19/002,013

(22) Filed: Dec. 26, 2024

Related U.S. Application Data
(60) Provisional application No. 63/614,988, filed on Dec. 27, 2023.

(51) Int. Cl. H10B 12/00

(52) U.S. Cl. CPC H10B 12/315; H10B 12/05

(57) ABSTRACT

A variety of applications can include an apparatus having an electronic device including a number of transistors in a pair-wise arrangement that can enhance on-state current. The transistors of the pair can be structured as transistors having a single-gate separated by a gate dielectric from a vertical channel structure. The pair-wise arrangement can include multiple conductive shields between a channel structure of a transistor of the pair and a channel structure of the other transistor of the other pair. The multiple conductive shields can be stacked vertically on each other with each given conductive shield in the stack contacting another conductive shield above or below the given conductive shield. The multiple conductive shields can include a low work function material and a high work function material.

### PRIORITY APPLICATION

This application claims the benefit of priority to U.S. Provisional Application Ser. No. 63/614,988, filed Dec. 27, 2023, which is incorporated herein by reference in its entirety.

### FIELD OF THE DISCLOSURE

Embodiments of the disclosure relate generally to electronic devices and, more specifically, to memory devices, transistors and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the design and fabrication of components of the electronic devices such as components of memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates a cross-sectional representation of an example electronic device having two vertical transistors with two conductive shields structured between the two vertical transistors, according to various embodiments.

FIG. 2 illustrates a cross-sectional representation of an example electronic device having two vertical transistors with three conductive shields structured between the two vertical transistors, according to various embodiments.

FIG. 3 illustrates a cross-sectional representation of an example memory device having pairs of vertical transistors with multiple conductive shields structured between the two vertical transistors of each of the pairs in the memory device, according to various embodiments.

FIG. 4 is a schematic of an example dynamic random-access memory memory device that can include an arrangement similar to the arrangement of the memory device of FIG. 3, according to various embodiments.

FIGS. 5-9 illustrate a process flow of an example method of forming a pair of single-gate vertical transistors with multiple conductive shields formed between the vertical transistors, according to various embodiments.

FIG. 10 is a flow diagram of features of an example method of forming an electronic device having a pair of single-gate vertical transistors with conductive shields between the single-gate vertical transistors, according to various embodiments.

FIG. 11 is a block diagram illustrating an example of a machine that can be implemented with one or more devices having a pair of single-gate vertical transistors with conductive shields between the vertical transistors of the pair, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

As complexity and capacity criteria increase, components of electronic devices are being scaled down in size. To increase storage capacity, sizes of memory cells are being reduced. For example, DRAM devices are increasing in memory capacity with reduced memory cell size or other design considerations. However, DRAM device scaling can become difficult. One option, to address reducing cell size, can include using a vertical channel of a single-gate transistor as an access device in each memory cell. The memory cell can be structured as the access device coupled to a storage cell, where the storage cell can be a capacitor. The capacitor can be realized in a number of different formats. A single-gate transistor can be referred to as a one-gate transistor. The transistor can be structured as a thin film transistor (TFT). TFTs are a class of metal-oxide-semiconductor field-effect transistors (MOSFETs).

There are some challenges associated with using a TFT with a vertical channel structure as an access device of a memory cell. In a conventional complex of densely spaced single-gate transistors, with one gate on a side of the channel structure of the single-gate transitor, the other side of the channel structure can be electrostatically coupled to an adjacent single-gate transistor. A shield can be positioned between adjacent single-gate transistors to reduce electrostatic coupling. Additionally, a TFT, as an access device, can put a constraint on the junction of the TFT that is on the data line side of the TFT and on the junction of the TFT that is on the storage cell side of the TFT, which can impact the current, I_{ON}, where I_{ON} is the on-state current of the transistor. The current, I_{OFF}, is the off-state current of the transistor. A n-channel MOSFET, for example, is in the off-state when the voltage between the gate and the source of the MOSFET (V_{gs}) is less than the threshold voltage (Vₜ). The subthreshold current, when V_{gs}<Vₜ, is a main contributor to I_{OFF}. Measured I_{OFF} is the drain current (I_{d}) measured at V_{gs}=0 with the voltage between the drain and the source (V_{ds}) at the level of the supply voltage. The ratio, I_{ON}/I_{OFF}, is a figure of merit for high performance and low leakage power for the transistor. High performance is associated with more I_{ON} and low leakage power is associated with less I_{OFF}. Eliminating or significantly reducing sub-surface conduction can improve the I_{ON}/I_{OFF} ratio.

In various embodiments, a memory array having single-gate devices can include multiple shields between adjacent single-gate transistor devices that can mitigate I_{ON} problems and improve I_{OFF}. The single-gate devices can be structured with a design that also also boosts I_{ON}, while improving I_{OFF}. The multiple shields can be structured with materials of high work function and low work function connected together. A work function is as the minimum amount of energy to remove an electron from a solid to a point in the vacuum immediately outside the solid surface. Herein, a given material is defined as being a high work function material if the work function of the given material is equal to or greater than 4.65 eV. A low work function material, such as a metal, can help reduce electric fields in the junctions of adjacent single-gate transistor devices, which in turn can reduce I_{OFF} improving refresh procedures.

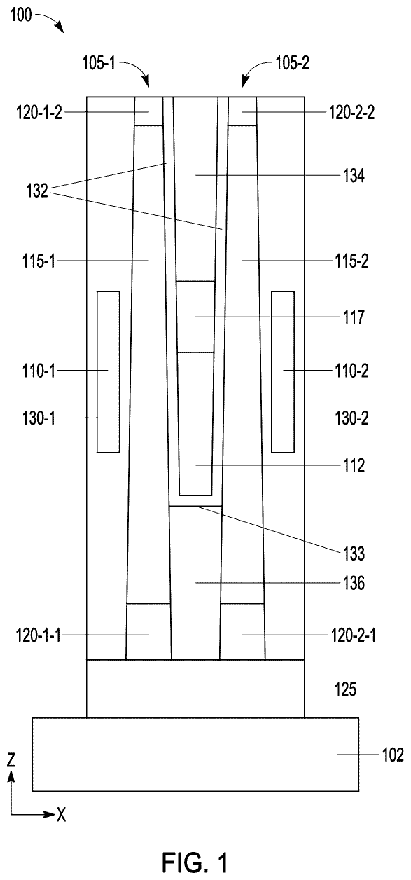

FIG. 1 illustrates a cross-sectional representation of an embodiment of an example electronic device 100 having two vertical transistors with two conductive shields structured between the two vertical transistors. A vertical transistor 105-1 and a vertical transistor 105-2 can be structured with a conductive shield 112 and conductive shield 117 structured between the two vertical transistors 105-1 and 105-2. Each of transistor 105-1 and transistor 105-2 can be structured as a TFT. Transistor 105-1 can include a source/drain region 120-1-1 and a source/drain region 120-1-2 at opposite ends of a vertical pillar. Source/drain region 120-1-1 is at the bottom of the pillar and source/drain region 120-1-2 is at the top of the pillar. Source/drain region 120-1-1 and source/drain region 120-1-2 can be highly doped regions relative to the material of the pillar between source/drain region 120-1-1 and source/drain region 120-1-2. The region of the pillar between source/drain region 120-1-1 and source/drain region 120-1-2 provides a channel structure 115-1 for transistor 105-1. Gate 110-1 is separated from channel structure 115-1 by a gate dielectric 130-1.

Gate 110-1 can have a metallic composition. A metallic composition is a composition of one or more elemental metals or a composition of two or more elements such that the composition has electrical properties of a metal. A metallic composition can be structured having one or more elemental metals and one or more non-metal elements. The metallic composition can include one or more metals such as, but not limited to, W, Mo, and Ru. The metallic composition can include, but is not limited to, one or more of TiN or an appropriate metal silicide. The doping in the pillar can decrease from source/drain region 120-1-1 to a region opposite gate 110-1 of transistor 105-1 and then increase towards source/drain region 120-1-2. The pillar can include, but is not limited to, Si, polysilicon, or silicon germanium (SiGe). Source/drain region 120-1-1 is situated above a conductive region 125, which can be a metal line for communication such as current flow with an electronic device coupled to source/drain region 120-1-2. There can be a region between source/drain region 120-1-1 and conductive region 125, where such a region can be a highly doped region to provide a conduction path, with relatively low resistance, between source/drain region 120-1-1 and conductive region 125. Conductive region 125 can include one or more of W, Ru, TiN, a metal silicide, or other metallic composition and can be structured above a substrate 102.

Transistor 105-2 can include a source/drain region 120-2-1 and a source/drain region 120-2-2 at opposite ends of a vertical pillar. Source/drain region 120-2-1 is at the bottom of the pillar and source/drain region 120-2-2 is at the top of the pillar. Source/drain region 120-2-1 and source/drain region 120-2-2 can be highly doped regions relative to the material of the pillar between source/drain region 120-2-1 and source/drain region 120-2-2. The region of the pillar between source/drain region 120-2-1 and source/drain region 120-2-2 provides a channel structure 115-2 for transistor 105-2. Gate 110-2 is separated from channel structure 115-2 by a gate dielectric 130-2.

Gate 110-2 can have a metallic composition. The metallic composition can include one or more metals such as, but not limited to, W, Mo, and Ru. The metallic composition can include, but is not limited to, one or more of TiN or an appropriate metal silicide. The doping in the pillar can decrease from source/drain region 120-2-1 to a region opposite gate 110-2 of transistor 105-2 and then increase towards source/drain region 120-2-2. The pillar can include, but is not limited to, Si, polysilicon, or SiGe. Source/drain region 120-2-1 is situated above conductive region 125, which can be a metal line for communication such as current flow with an electronic device coupled to source/drain region 120-2-2. There can be a region between source/drain region 120-2-1 and conductive region 125, where such a region can be a highly doped region to provide a conduction path, with relatively low resistance, between source/drain region 120-2-1 and conductive region 125.

Transistor 105-1 and transistor 105-2 can be fabricated in a common process, which can result in similar or identical structures. Transistor 105-1 and transistor 105-2 can be structured as access devices from a common location such as conductive region 125 to different components, where source/drain region 120-1-2 is coupled to a set of one or more components and source/drain region 120-2-2 is coupled to another different set of one or more components. Gate 110-1 of transistor 105-1 can be coupled to an access line in the y-direction (out of the plane of FIG. 1) and gate 110-2 of transistor 105-2 can be coupled to a different access line in the y-direction. In a DRAM device or other storage arrangement, conductive region 125 can be a data line coupled to source/drain region 120-1-1 and source/drain region 120-2-1 with source/drain region 120-1-2 coupled to one capacitor and source/drain region 120-1-2 coupled to another different capacitor.

Conductive shield 112 and conductive shield 117 can be separated from transistor 105-1 by a dielectric liner 132 and conductive shield 112 and conductive shield 117 can be separated from transistor 105-2 by the same dielectric liner 132. Dielectric liner 132 is a dielectric structure having a first surface contacting channel structure 115-1 and a second surface contacting channel structure 115-2. A dielectric structure is a structure having one or more dielectric materials defining the structure to be a dielectric. The thickness of dielectric liner 132 can be different from the thickness of gate dielectric 130-1 or gate dielectric 130-2. Alternatively, the thickness of dielectric liner 132 can be the same as the thickness of gate dielectric 130-1 or gate dielectric 130-2. Conductive shield 112 can be on and contacting a lower horizontal surface 133 of dielectric liner 132. The thickness of dielectric liner 132 along lower horizontal surface 133 can be different from the thickness of dielectric liner 132 extending vertically from lower horizontal surface 133. A dielectric region 134 can be positioned on and contacting conductive shield 117 and can be between the first surface and the second surface of dielectric liner 132. Dielectric region 134 and dielectric liner 132 can have a common composition. Alternatively, dielectric region 134 and dielectric liner 132 can have different compositions. Lower horizontal surface 133 of the dielectric liner 132 can be structured on another dielectric region 136 that is positioned on and above conductive region 125. Dielectric region 136 can be a portion of an isolation dielectric implemented in which transistors 105-1 and 105-2 can be structured.

Conductive shield 112 located within dielectric liner 132 between channel structure 115-1 of transistor 105-1 and channel structure 115-2 of transistor 105-2 can be a metal or a metallic composition. Conductive shield 117 located within dielectric liner 132 between channel structure 115-1 of transistor 105-1 and channel structure 115-2 of transistor 105-2 can be a metal, a metallic composition, or n+ polysilicon. The combination of conductive shield 117 on and contacting conductive shield 112 can be coupled to a constant voltage supply. The constant voltage supply can be at zero volts or at a negative voltage. Various dielectric materials, which can be used in electronic device 100 of FIG. 1, can include, but are not limited to, silicon oxide (SiO_{X}), silicon nitride (SiN_{X}), silicon oxynitride (SiO_{X}N_{Y}), other appropriate dielectrics, or combinations of dielectrics. The choice of dielectric materials for each of these regions can be selected based of the application for which transistors 105-1 and 105-2 are implemented or based on the efficiencies provided in the fabrication process flow.

Conductive shield 112 and conductive shield 117 structured as a vertical stack with conductive shield 117 above and contacting conductive shield 112 effectively defines a conductive shield of dual conductor materials. Conductive shield 112 can be a high work function material and conductive shield 117 can be a low work function material. For example, conductive shield 117 can be a material having a work function close to 4.1 eV. Low work functions can include, but are not limited to, Ti, TiSiN, and n+ doped polysilicon. High work functions can include, but are not limited to, TiN, W, Mo, and Ru. Material of gate 110-1 can be a high work function material and material of gate 110-2 can be a high work material. Material of gate 110-1 and material of gate 110-2 can be, but are not limited to, the same high work material as the high work material of conductive shield 112. The stack of conductive shield 117 on and contacting conductive shield 112 can be structured within dielectric liner 132 in a number of arrangements. For example, portions of conductive shield 117 and portions of conductive shield 112 can be at a level (height) from a top surface of substrate 102 equal to portions of gate 110-1 and gate 110-2.

The arrangement of two transistors 105-1 and 105-2 of electronic device 100 can be implemented in a memory device with each of two transistors 105-1 and 105-2 being part of two different memory cells coupled to the same data line. The data line can be realized by conductive region 125. In a memory array of such a memory device, gate 110-1 of transistor 105-1 and gate 110-2 of transistor 105-2 are coupled to different access lines. With conductive shield 112 being a high work function material and conductive shield 117 being a low work function material, structured as shown in FIG. 1, transistors 105-1 and 105-2 can achieve a significant boost in I_{ON} and improvied I_{OFF}. The boost in I_{ON} may be in the range of an approximate 35% boot.

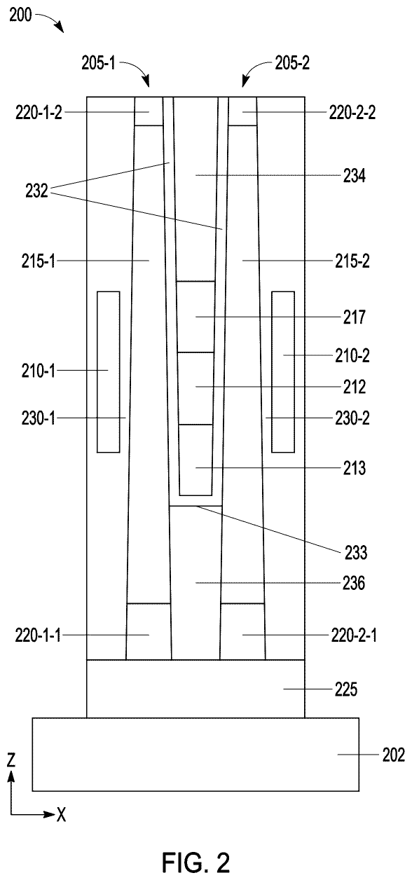

FIG. 2 illustrates a cross-sectional representation of an embodiment of an example electronic device 200 having of two vertical transistors with three conductive shields structured between the two vertical transistors. A vertical transistor 205-1 and a vertical transistor 205-2 can be structured with a conductive shield 213, a conductive shield 212, and a conductive shield 217 structured between the two vertical transistors 205-1 and 205-2. Each of transistor 205-1 and transistor 205-2 can be structured as a TFT. Transistor 205-1 can include a source/drain region 220-1-1 and a source/drain region 220-1-2 at opposite ends of a vertical pillar. Source/drain region 220-1-1 is at the bottom of the pillar and source/drain region 220-1-2 is at the top of the pillar. Source/drain region 220-1-1 and source/drain region 220-1-2 can be highly doped regions relative to the material of the pillar between source/drain region 220-1-1 and source/drain region 220-1-2. The region of the pillar between source/drain region 220-1-1 and source/drain region 220-1-2 provides a channel structure 215-1 for transistor 205-1. Gate 210-1 is separated from channel structure 215-1 by a gate dielectric 230-1.

Gate 210-1 can have a metallic composition. The metallic composition can include one or more metals such as, but not limited to, W, Mo, and Ru. The metallic composition can include, but is not limited to, one or more of TiN or an appropriate metal silicide. The doping in the pillar can decrease from source/drain region 220-1-1 to a region opposite gate 210-1 of transistor 205-1 and then increase towards source/drain region 220-1-2. The pillar can include, but is not limited to, Si, polysilicon, or SiGe. Source/drain region 220-1-1 is situated above a conductive region 225, which can be a metal line for communication such as current flow with an electronic device coupled to source/drain region 220-1-2. There can be a region between source/drain region 220-1-1 and conductive region 225, where such a region can be a highly doped region to provide a conduction path, with relatively low resistance, between source/drain region 220-1-1 and conductive region 225. Conductive region 225 can include one or more of W, Ru, TiN, a metal silicide, or other metallic composition and can be structured above a substrate 202.

Transistor 205-2 can include a source/drain region 220-2-1 and a source/drain region 220-2-2 at opposite ends of a vertical pillar. Source/drain region 220-2-1 is at the bottom of the pillar and source/drain region 220-2-2 is at the top of the pillar. Source/drain region 220-2-1 and source/drain region 220-2-2 can be highly doped regions relative to the material of the pillar between source/drain region 220-2-1 and source/drain region 220-2-2. The region of the pillar between source/drain region 220-2-1 and source/drain region 220-2-2 provides a channel structure 215-2 for transistor 205-2. Gate 210-2 is separated from channel structure 215-2 by a gate dielectric 230-2.

Gate 210-2 can have a metallic composition. The metallic composition can include one or more metals such as, but not limited to, W, Mo, and Ru. The metallic composition can include, but is not limited to, one or more of TiN or an appropriate metal silicide. The doping in the pillar can decrease from source/drain region 220-2-1 to a region opposite gate 210-2 of transistor 205-2 and then increase towards source/drain region 220-2-2. The pillar can include, but is not limited to, Si, polysilicon, or SiGe. Source/drain region 220-2-1 is situated above conductive region 225, which can be a metal line for communication such as current flow with an electronic device coupled to source/drain region 220-2-2. There can be a region between source/drain region 220-2-1 and conductive region 225, where such a region can be a highly doped region to provide a conduction path, with relatively low resistance, between source/drain region 220-2-1 and conductive region 225.

Transistor 205-1 and transistor 205-2 can be fabricated in a common process, which can result in similar or identical structures. Transistor 205-1 and transistor 205-2 can be structured as access devices from a common location such as conductive region 225 to different components, where source/drain region 220-1-2 is coupled to a set of one or more components and source/drain region 220-2-2 is coupled to another different set of one or more components. Gate 210-1 of transistor 205-1 can be coupled to an access line in the y-direction (out of the plane of FIG. 2) and gate 210-2 of transistor 205-2 can be coupled to a different access line in the y-direction. In a DRAM device or other storage arrangement, conductive region 225 can be a data line coupled to source/drain region 220-1-1 and source/drain region 220-2-1 with source/drain region 220-1-2 coupled to one capacitor and source/drain region 220-1-2 coupled to another different capacitor.

Conductive shield 212, conductive shield 213, and conductive shield 217 can be separated from transistor 205-1 by a dielectric liner 232, and conductive shield 212, conductive shield 213, and conductive shield 217 can be separated from transistor 205-2 by the same dielectric liner 232. Dielectric liner 232 is a dielectric structure having a first surface contacting channel structure 215-1 and a second surface contacting channel structure 215-2. Conductive shield 213 can be on and contacting a lower horizontal surface 233 of dielectric liner 232. A dielectric region 234 can be positioned on and contacting conductive shield 217 and can be between the first surface and the second surface of dielectric liner 232. Dielectric region 234 and dielectric liner 232 can have a common composition. Alternatively, dielectric region 234 and dielectric liner 232 can have different compositions. Lower horizontal surface 233 of the dielectric liner 232 can be structured on another dielectric region 236 that is positioned on and above conductive region 225. Dielectric region 236 can be a portion of an isolation dielectric implemented in which transistors 205-1 and 205-2 can be structured.

Conductive shield 212 located within dielectric liner 232 between channel structure 215-1 of transistor 205-1 and channel structure 215-2 of transistor 205-2 can be a metal or a metallic composition. Conductive shield 213 located within dielectric liner 232 between channel structure 215-1 of transistor 205-1 and channel structure 215-2 of transistor 205-2 can be a metal, a metallic composition, or n+ polysilicon. Conductive shield 217 located within dielectric liner 232 between channel structure 215-1 of transistor 205-1 and channel structure 215-2 of transistor 205-2 can be a metal, a metallic composition, or n+polysilicon. The combination of conductive shield 217 on and contacting conductive shield 212 and conductive shield 212 on and contacting conductive shield 213 can be coupled to a constant voltage supply. The constant voltage supply can be at zero volts or at a negative voltage. Various dielectric materials, which can be used in electronic device 200 of FIG. 2, can include, but are not limited to, SiO_{X}, SiN_{X}, SiO_{X}N_{Y}, other appropriate dielectrics, or combinations of dielectrics. The choice of dielectric materials for each of these regions can be selected based of the application for which transistors 205-1 and 205-2 are implemented or based on the efficiencies provided in the fabrication process flow.

Conductive shield 213, conductive shield 212, and conductive shield 217, structured as a vertical stack with conductive shield 217 above and contacting conductive shield 212 and conductive shield 212 above and contacting conductive shield 213, effectively defines a conductive shield of three conductor materials. Alternatively, a conductive shield of more than three conductor materials can be structured between two transistors in an arrangement such as shown in FIG. 1 or 2. Conductive shield 212 can be a high work function material; conductive shield 213 can be a low work function material; and conductive shield 217 can be a low work function material. Material of gate 210-1 can be a high work function material and material of gate 210-2 can be a high work material. Material of gate 210-1 and material of gate 210-2 can be, but are not limited to, the same high work material as the high work material of conductive shield 212. Conductive shield 212 can be a high work function metal. Conductive shield 213 can be a low work function metal or low work function n+polysilicon and conductive shield 217 can be a low work function metal or low work function n+polysilicon. For example, conductive shield 217 or conductive shield 213 can be a material having a work function close to 4.1 eV. The stack of conductive shield 217 on and contacting conductive shield 212 with conductive shield 212 on and contacting conductive shield 213 can be structured within dielectric liner 232 in a number of arrangements. For example, portions of conductive shield 217, portions of conductive shield 212, and portions of conductive shield 213 can be at a level (height) from a top surface of substrate 202 equal to portions of gate 210-1 and gate 210-2.

The arrangement of two transistors 205-1 and 205-2 of electronic device 200 can be implemented in a memory device with each of two transistors 205-1 and 205-2 being part of two different memory cells coupled to the same data line. The data line can be realized by conductive region 225. In a memory array of such a memory device, gate 210-1 of transistor 205-1 and gate 210-2 of transistor 205-2 are coupled to different access lines.

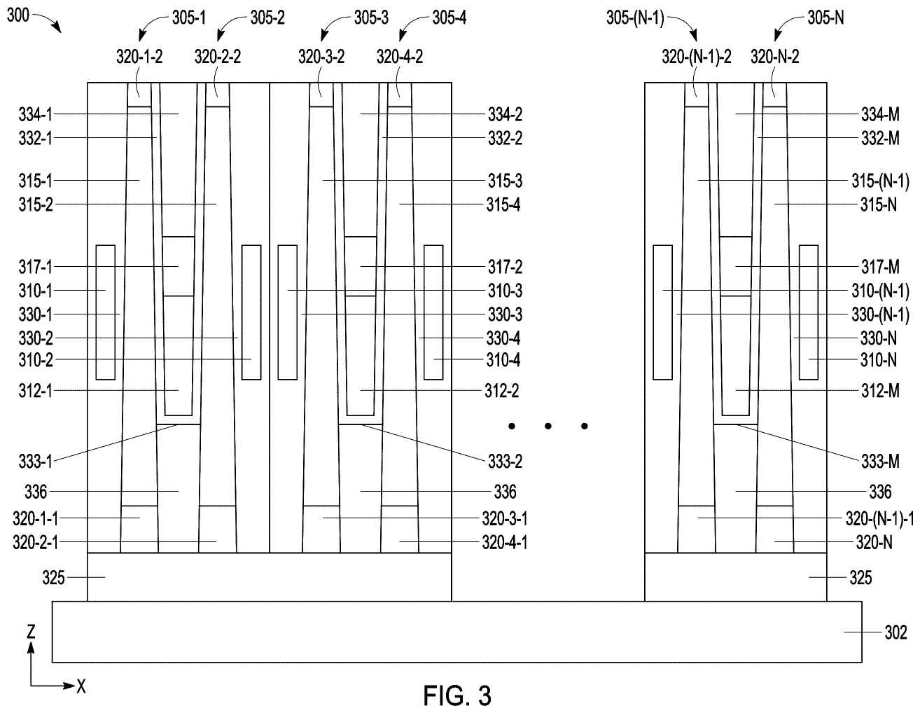

FIG. 3 illustrates a cross-sectional representation of an embodiment of an example memory device 300 having pairs of vertical transistors with multiple conductive shields structured between the two vertical transistors of each of the pairs in a memory device 300. In the example of FIG. 3, the multiple conductive shields are two in number, though more than two conductive shields can be structured between two vertical transistors. The transistor structures of FIG. 1, FIG. 2, or similar structures can be implemented in memory device 300. Memory device 300 can include a pair having transistors 305-1 and 305-2, a pair having transistors 305-3 and 305-4 . . . and a pair having transistors 305-(N−1) and 305-N, with all the transistors on and coupled to a conductive data line 325. Transistors 305-1, 305-2, 305-3, 305-4 . . . 305 (N−1), and 305-N can be structured as access devices to storage elements of different memory cells. The storage elements can be capacitors. The capacitors can be realized in a number of different formats. Though transistors 305-1, 305-2, 305-3, 305-4 . . . 305-(N−1), and 305-N are coupled to the same conductive data line 325, each one of transistors 305-1, 305-2, 305-3, 305-4 . . . 305-(N−1) and 305-N are coupled to an access line at their respective gates, where each access line is different for the different transistors coupled to the same data line. Each one of transistors 305-1, 305-2, 305-3, 305-4 . . . 305-(N−1) and 305-N can be structured as a TFT with a single gate. Memory device 300 can include multiple data lines arranged similar to conductive data line 325, where the multiple data lines are separate, non-contacting data lines, and pairs of single-gate transistors coupled to the data lines.

The access transistors of memory device 300 can be structured in design and with materials similar to transistors 105-1 and 105-2 with multiple conductive shields structured between the two transistors 105-1 and 105-2, as shown in FIG. 1, or similar to transistors 205-1 and 205-2 with multiple conductive shields structured between the two transistors 205-1 and 205-2, as shown in FIG. 2. Transistors 305-1, 305-2, 305-3, 305-4 . . . 305-(N−1) and 305-N can include source/drain regions 320-1-1 and 320-1-2, source/drain regions 320-2-1 and 320-2-2, source/drain regions 320-3-1 and 320-3-2, source/drain regions 320-4-1 and 320-4-2 . . . source/drain regions 320-(N−1)-1 and 320-(N−1)-2, and source/drain regions 320-N−1 and 320-N-2, respectively, at opposite ends of different pillars that provide channel structures 315-1, 315-2, 315-3, 315-4 . . . 315-(N−1), and 315-N, respectively. Transistors 305-1, 305-2, 305-3, 305-4 . . . 305-(N−1) and 305-N can include a single gate 310-1, 310-2, 310-3, 310-4 . . . 310-(N−1), and 310-N, respectively, separated from channel structures 315-1, 315-2, 315-3, 315-4 . . . 315-(N−1), and 315-N by gate dielectrics 330-1, 330-2, 330-3, 330-4 . . . 330-(N−1), and 330-N, respectively. Transistors 305-1, 305-2, 305-3, 305-4 . . . 305-(N−1) and 305-N are separated from each other by a dielectric region 336 that provides isolation for these transistors. Each gate of gates 310-1, 310-2, 310-3, 310-4 . . . 310-(N−1), and 310-N can individually be structured as part of an individual access line or coupled to the individual access line.

Gates 310-1, 310-2, 310-3, 310-4 . . . 310-(N−1), and 310-N can have a metallic composition. The metallic composition can include one or more metals such as, but not limited to, W, Mo, and Ru. The metallic composition can include, but is not limited to, one or more of TiN or an appropriate metal silicide. The doping in each pillar of transistors 305-1, 305-2, 305-3, 305-4 . . . 305-(N−1) and 305-N can decrease from a source/drain regions 320-1-1, 320-2-1, 320-3-1, 320-4-1 . . . 320-(N−1)-1, and 320-N−1, respectively, to a region opposite gates 310-1, 310-2, 310-3, 310-4 . . . 310-(N−1), and 310-N of transistors 305-1, 305-2, 305-3, 305-4 . . . 305-(N−1) and 305-N, respectively, and then increase towards source/drain regions 320-1-2, 320-2-2, 320-3-2, 320-4-2 . . . 320-(N−1)-2, and 320-N-2. The pillars can include, but are not limited to, Si, polysilicon, or SiN. Source/drain regions 320-1-1, 320-2-1, 320-3-1, 320-4-1 . . . 320-(N−1)-1, and 320-N−1 are situated above a conductive data line 325, which can be a metal line for communication such as current flow with an electronic device coupled to source/drain regions 320-1-2, 320-2-2, 320-3-2, 320-4-2 . . . 320-(N−1)-2, and 320-N-2. There can be a region between source/drain region 320-1-1 and conductive data line 325, where such a region can be a highly doped region to provide a conduction path, with relatively low resistance, between source/drain region 320-1-1, 320-2-1, 320-3-1, 320-4-1 . . . 320-(N−1)-1 and conductive data line 325. Conductive data line 325 can include one or more of W, Ru, TiN, a metal silicide, or other metallic composition and can be structured above a substrate 302.

A conductive shield 317-1 on and contacting a conductive shield 312-1 can be located within a dielectric liner 332-1 between channel structure 315-1 of transistor 305-1 and channel structure 315-2 of transistor 305-2. A conductive shield 317-2 on and contacting a conductive shield 312-2 can be located within a dielectric liner 332-2 between channel structure 315-3 of transistor 305-3 and channel structure 315-4 of transistor 305-4. A conductive shield 317-M on and contacting a conductive shield 312-M can be located within a dielectric liner 332-M between channel structure 315-(N−1) of transistor 305-(N−1) and channel structure 315-N of transistor 305-N. The same structure can be implemented in the series of pairs of vertical transistors on and along conductive data line 325. Conductive shields 312-j, j=1, 2 . . . M, can be a metal or a metallic composition. Conductive shield 317-j, j=1, 2 . . . M can be a metal, a metallic composition, or n+ polysilicon. The combination of conductive shield 317-j on and contacting conductive shield 312-j can be coupled to a constant voltage supply. The constant voltage supply can be at zero volts or at a negative voltage. Various dielectric materials, which can be used in electronic device 300 of FIG. 3, can include, but are not limited to, SiO_{X}, SiN_{X}, SiO_{X}N_{Y}, other appropriate dielectrics, or combinations of dielectrics. The choice of dielectric materials for each of these regions can be selected based of the application for which transistors 305-1, 305-2, 305-3, 305-4 . . . 305-(N−1) and 305-N are implemented or based on the efficiencies provided in the fabrication process flow.

Conductive shield 312-j, j=1, 2 . . . M, and conductive shield 317-j, j=1, 2 . . . M, structured as a vertical stack with conductive shield 317-j, j=1, 2 . . . M, above and contacting conductive shield 312-j, j=1, 2 . . . M, effectively define conductive shields of dual conductor materials. Conductive shield 312-j, j=1, 2 . . . M, can be a high work function material and conductive shield 317, j=1, 2 . . . M, can be a low work function material. Material of gates 310-1, 310-2, 310-3, 310-4 . . . 310-(N−1), and 310-N can be high work function materials. Material of each of gates 310-1, 310-2, 310-3, 310-4 . . . 310-(N−1), and 310-N can be, but are not limited to, the same high work material as the high work material of conductive shields 312-j, j=1, 2 . . . M. Conductive shields 312-j, j=1, 2 . . . M, can be a high work function metal. Conductive shield 317-j, j=1, 2 . . . M, can be a low work function metal or low work function n+ polysilicon. For example, conductive shield 317-j, j=1, 2 . . . M, can be material having a work function close to 4.1 eV. The stack of conductive shield 317-j, j=1, 2 . . . M, on and contacting conductive shield 312-j, j=1,2 . . . M, can be structured within dielectric liner 332-j, j=1, 2 . . . M, respectively, in a number of arrangements. For example, portions of a conductive shield 317-j, j=1, 2 . . . M, and portions of conductive shield 312-j, j=1, 2 . . . M, can be at a level (height) from a top surface of substrate 302 equal to portions of corresponding gates 310-1, 310-2, 310-3, 310-4 . . . 310-(N−1), and 310-N.

Using TFT having a single gate opposite a vertical channel can be implemented in the array of memory device 300 to provide increased capacity. The increased capacity can be attained by scaling, taking into consideration the effects of the scaling, to reduce the size of the memory cells of the array. The transistors, as taught herein, can be structured to provide a 4F2 memory cell.

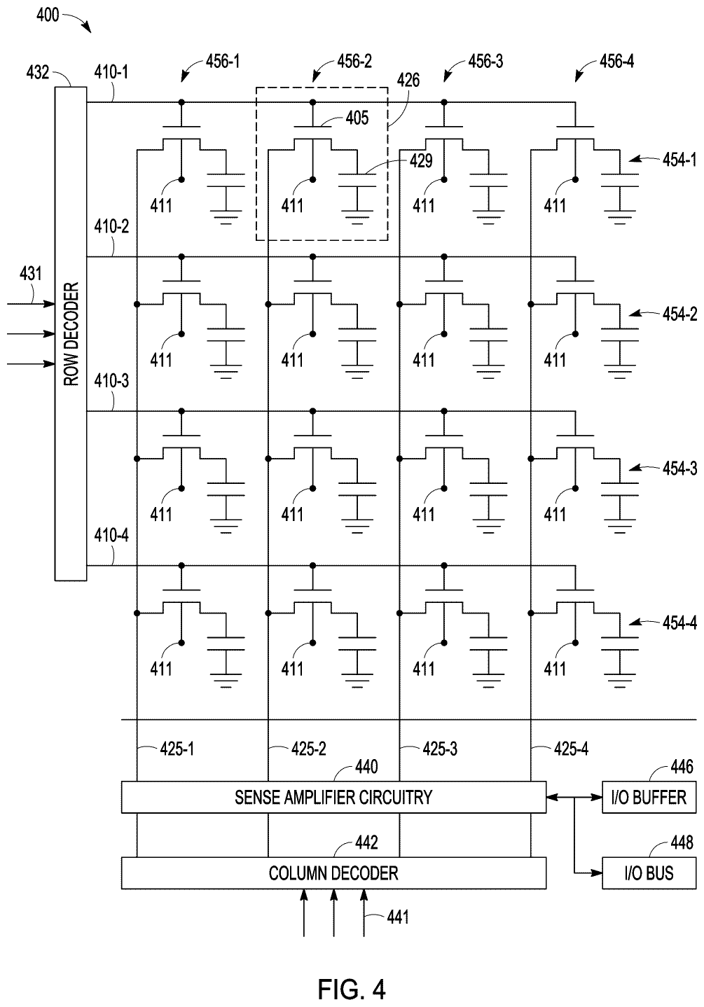

FIG. 4 is a schematic of an embodiment of an example DRAM device 400 that can include an arrangement of pairs of transistors similar to the arrangement of memory device 300 of FIG. 3. DRAM device 400 includes an array of memory cells 426 (only one being labeled in FIG. 4 for ease of presentation) arranged in rows 454-1, 454-2, 454-3, and 454-4 and columns 456-1, 456-2, 456-3, and 456-4. For simplicity and ease of discussion, the array is shown in only two dimensions, but the array can be extended into the third dimension. Further, while only four rows 454-1, 454-2, 454-3, and 454-4 and four columns 456-1, 456-2, 456-3, and 456-4 of four memory cells are illustrated, DRAM devices like DRAM device 400 can have significantly more memory cells 426 (e.g., tens, hundreds, or thousands of memory cells) per row or per column.

Each memory cell 426 can include a single transistor 405 and a single capacitor 429, which is commonly referred to as a 1TIC (one-transistor-one capacitor cell). Transistor 405 can be implemented as a TFT having a single gate (one-gate). One plate of capacitor 429, which can be termed the “node plate,” is connected to a source/drain terminal of transistor 405, whereas the other plate of the capacitor 429 is connected to ground 424. Each capacitor 429 within the array of 1TIC cells 426 typically serves to store one bit of data, and the respective transistor 405 serves as an access device to write to or read from storage capacitor 429.

The transistor gate terminals within each row of rows 454-1, 454-2, 454-3, and 454-4 are portions of respective access lines 410-1, 410-2, 410-3, and 410-4 (alternatively referred to as “word lines”), and transistor source/drain terminals within each of columns 456-1, 456-2, 456-3, and 456-4 are electrically connected to respective data lines 425-1, 425-2, 425-3, and 425-4 (alternatively referred to as “bit lines”). The pair of transistors coupled to access line 410-1 and access line 410-2, respectively, and to data line 410-1 can be structured, similar to transistors 105-1 and 105-2 of electronic device 100 of FIG. 1 or transistors 205-1 and 205-2 of memory device 200 of FIG. 2, with stacked multiple conductive shields between adjacent transistors. The stacked multiple conductive shields between the adjacent transistors that are coupled to a data line can be coupled to a node 411 to receive a voltage that DRAM device 400 can set to a constant voltage in operation, such as zero volts or a negative voltage. The pair of transistors coupled to accesss line 410-3 and access line 410-4, respectively, and also to data line 425-1 can be structured, similar to transistors 105-1 and 105-2 of electronic device 100 of FIG. 1 or transistors 205-1 and 205-2 of memory device 200 of FIG. 2, with stacked multiple conductive shields between the adjacent transistors. The stacked multiple conductive shields can be connected to a node 411 to receive a voltage that DRAM device can set to a constant voltage in operation, such as zero volts or a negative voltage. The other vertical transistors of the memory array of DRAM device 400 can be structured in a similar pair-wise arrangement with stacked multiple conductive shields between the adjacent vertical transistors, where the stacked conductive shields can be connected to a node 411 to receive a voltage that DRAM device 400 can set to a constant voltage in operation. The nodes 411 can be individually connected to a voltage source in DRAM device 400 or one or more of the nodes 411 can be coupled together in DRAM device 400 to receive a voltage.

A row decoder 442 can selectively drive the individual access lines 410-1, 410-2, 410-3, and 410-4, responsive to row address signals 431 input to row decoder 432. Driving a given access line at a high voltage causes the access transistors within the respective row to conduct, thereby connecting the storage capacitors within the row to the respective data lines, such that charge can be transferred between the data lines and the storage capacitors for read or write operations. Both read and write operations can be performed via sense amplifier circuitry 440, which can transfer bit values between the memory cells 426 of the selected row of the rows 454-1, 454-2, 454-3, and 454-4 and input/output buffers 446 (for write/read operations) or external input/output data buses 448.

A column decoder 442 responsive to column address signals 441 can select which of the memory cells 426 within the selected row is read out or written to. Alternatively, for read operations, the storage capacitors 429 within the selected row can be read out simultaneously and latched, and the column decoder 442 can then select which latch bits to connect to the output data bus 448. Since read-out of the storage capacitors destroys the stored information, the read operation can be accompanied by a simultaneous rewrite of the capacitor charge. Further, in between read/write operations, the capacitor charge can be repeatedly refreshed to prevent data loss. Details of read/rewrite, write, and refresh operations are well-known to those of ordinary skill in the art.

DRAM device 400 may be implemented as an integrated circuit within a package that includes pins for receiving supply voltages, for example, to provide the source and gate voltages for the transistors 405, and signals including data, address, and control signals. FIG. 4 depicts DRAM device 400 in simplified form to illustrate basic structural components, omitting many details of the memory cells 426 and associated access lines 410-1, 410-2, 410-3, and 410-4 and data lines 425-1, 425-2, 425-3, and 425-4 as well as the peripheral circuitry. For example, in addition to the row decoder 432 and column decoder 442, sense amplifier circuitry 440, and buffers 446, DRAM device 400 can include further peripheral circuitry, such as a memory control unit that controls the memory operations based on control signals (provided, e.g., by an external processor), additional input/output circuitry, etc. Details of such peripheral circuitry are generally known to those of ordinary skill in the art and not further discussed herein.

In two-dimensional (2D) DRAM arrays, the rows 454-1, 454-2, 454-3, and 454-4 and columns 456-1, 456-2, 456-3, and 456-4 of memory cells 426 can be arranged along a single horizontal plane (i.e., a plane parallel to the layers) of the semiconductor substrate, e.g., in a rectangular lattice with mutually perpendicular horizontal access lines 410-1, 410-2, 410-3, and 410-4 and data lines 425-1, 425-2, 425-3, and 425-4. In 3D DRAM arrays, the memory cells 426 are arranged in a 3D lattice that encompasses multiple vertically stacked horizontal planes corresponding to multiple device tiers of a multi-tier substrate assembly, with each device tier including multiple parallel rows of cells 426 whose transistor gate terminals are connected by horizontal access lines such as access lines 410-1, 410-2, 410-4, and 410-4. (A “device tier,” as used herein, can include multiple layers (or levels) of materials, but forms the components of memory devices of a single horizontal tier of memory cells.) Data lines 425-1, 425-2, 425-3, and 425-4 can be structured to extend vertically through all or at least a vertical portion of the multi-tier structure, and each of the data lines 425-1, 425-2, 425-3, and 425-4 connects to the appropriate transistor source/drain terminals of associated memory cells 426 at the multiple device tiers. Such a 3D configuration of memory cells can enable further increases in bit density compared with 2D arrays. Other arrangement of data lines and access lines can be implemented in a 3D DRAM.

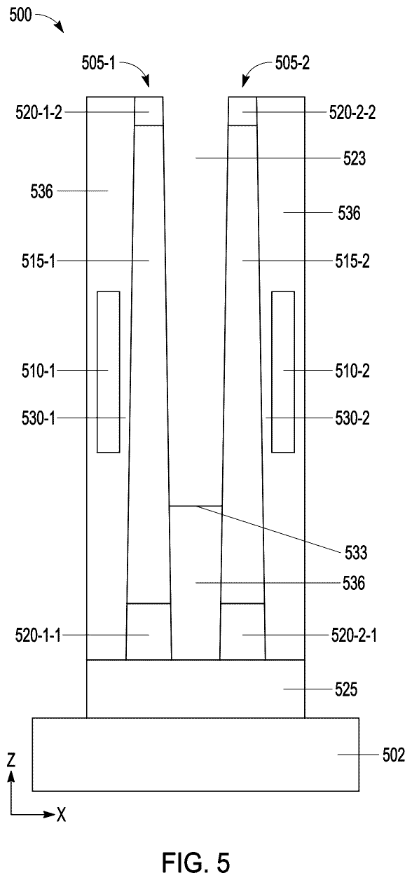

FIGS. 5-9 illustrate a process flow of an embodiment of an example method of forming a pair of single-gate vertical transistors with multiple conductive shields stacked between adjacent transistors. In this example process flow, the multiple conductive shields being formed define a conductive shield of dual conductor materials, though the multiple conductive shields are not limited to two conductive shields. FIG. 5 is a cross-sectional view of a structure 500 after processing that forms two transistors 505-1 and 505-2 in a dielectric isolation 536 above a conductive region 525 and that forms a trench 523 between transistor 405-1 and transistor 405-2. Transistor 405-1 and transistor 405-2 can be formed as TFTs. Formed transistor 405-1 can have a source/drain region 520-1-1 and a source/drain region 520-1-2 at opposite ends of a vertical pillar. Source/drain region 520-1-1 is at the bottom of the pillar and source/drain region 520-1-2 is at the top of the pillar. Source/drain region 520-1-1 and source/drain region 520-1-2 can be highly doped regions relative to the material of the pillar between source/drain region 520-1-1 and source/drain region 520-1-2. The region of the pillar between source/drain region 520-1-1 and source/drain region 520-1-2 has been formed providing a channel structure 515-1 for transistor 505-1. Gate 510-1 has been formed separated from channel structure 515-1 by a gate dielectric 530-1, where gate 510-1 has a metallic composition. The metallic composition can include one or more metals such as, but not limited to, W, Mo, and Ru. The metallic composition can include, but is not limited to, one or more of TiN or an appropriate metal silicide. The vertical pillar can be formed having a doping that decreases from source/drain region 520-1-2 to a region opposite a gate 510-1 and then increases towards source/drain region 520-1-1. The pillar can include, but is not limited to, Si, polysilicon, or SiGe. Source/drain region 520-1-1 is situated above conductive region 525. There can be a region between source/drain region 520-1-1 and conductive region 525, where such a region can be a highly doped region to provide a conduction path, with relatively low resistance, between source/drain region 520-1-1 and conductive region 525. Conductive region 525 can include one or more of W, Ru, TiN, a metal silicide, or other metallic composition and can be structured above a substrate 302.

Transistor 505-2 has been formed having a source/drain region 520-2-1 and a source/drain region 520-2-2 at opposite ends of a vertical pillar. Source/drain region 520-2-1 is at the bottom of the pillar and source/drain region 520-2-2 is at the top of the pillar. Source/drain region 520-2-1 and source/drain region 520-2-2 are highly doped regions relative to the material of the pillar between source/drain region 520-2-1 and source/drain region 520-2-2. The region of the pillar between source/drain region 520-2-1 and source/drain region 520-2-2 has been formed providing a channel structure 515-2 for transistor 505-2. Gate 510-2 has been formed separated from channel structure 515-2 by a gate dielectric 530-2, where gate 510-2 has a metallic composition. The metallic composition can include one or more metals such as, but not limited to, W, Mo, and Ru. The metallic composition can include, but is not limited to, one or more of TiN or an appropriate metal silicide. The vertical pillar can be formed having a doping that decreases from source/drain region 520-2-1 to region opposite a gate 510-2 and then increases towards source/drain region 520-2-2. The pillar can include, but is not limited to, Si, polysilicon, or SiGe. Source/drain region 520-2-1 is situated above conductive region 525. A region can be formed between source/drain region 520-2-1 and conductive region 525, where such a region can be a highly doped region to provide a conduction path, with relatively low resistance, between source/drain region 520-2-2 and conductive region 525.

Transistors 505-1 and 505-2 has been formed in dielectric isolation 536. Dielectric isolation 536 can be formed with the same or different material compositions of any one of gate dielectric 530-1 and gate dielectric 530-2. Various dielectrics that can be used include, but are not limited to, SiO_{X}, SiN_{X}, SiO_{X}N_{Y}, other appropriate dielectrics, or combinations of dielectrics. The choice of dielectric materials for each of these regions can be selected based of the application for which transistors 505-1 and 505-2 are to be implemented or based on the efficiencies provided in the fabrication process flow.

Portions of dielectric isolation 536 can be formed after forming transistors 505-1 and 505-2. Trench 523 can be formed by removing portions of dielectric isolation 536 between transistors 505-1 and 505-2. Trench 523 can be formed from at least the tops of transistors 505-1 and 505-2 down to a level 533 above conductive region 525, leaving a portion of dielectric isolation 536 above conductive region 525. Trench 523 can be formed using an appropriate etching technique selected for the material of dielectric isolation 536.

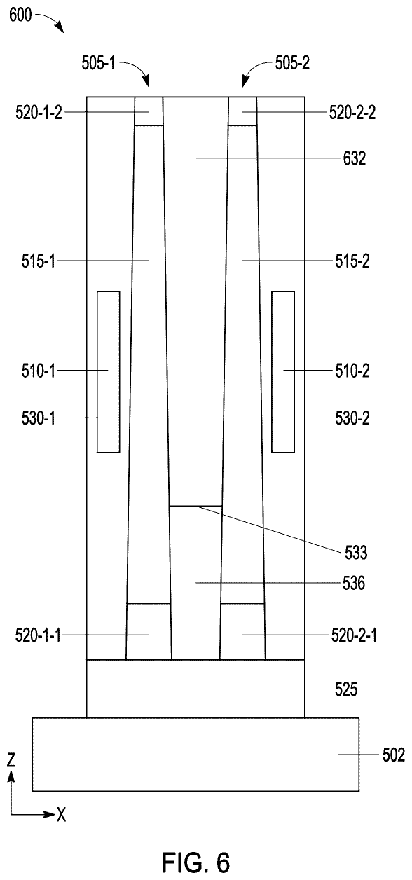

FIG. 6 is a cross-sectional view of a structure 600 after further processing structure 500 of FIG. 5. A shield dielectric material 632 has been formed in trench 523 of structure 500. Shield dielectric material 632 has been formed on the walls of the pillars of transistors 505-1 and 505-2 and the bottom of trench 523 at a level 533. Shield dielectric material 632 can be, but is not limited to, an oxide or other appropriate dielectric material. The oxide can be, but is not, limited to SiO_{X}. Shield dielectric material 632 can be formed by a deposition technique appropriate for the material of shield dielectric material 632.

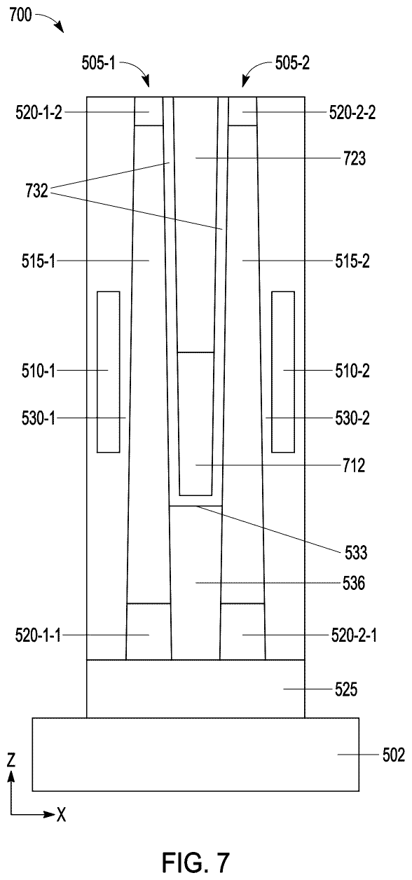

FIG. 7 is a cross-sectional view of a structure 700 after further processing structure 600 of FIG. 6. An inner portion of shield dilectric material 632 has been removed forming a dielectric liner 732 to a horizontal surface at level 533 that ends on dielectric isolation 536, where dielectric liner 732 has an opening. Material for a conductive shield has been formed in the opening of dielectric liner 732 and recessed forming a conductive shield 712 and opening 723 between walls of dielectric liner 732. Conductive shield 712 can be formed as a high work function material. Conductive shield 712 can be a high work function metal or high work function metal composition. Conductive shield 712 can be formed with the same material composition as gate 510-1 or gate 510-2.

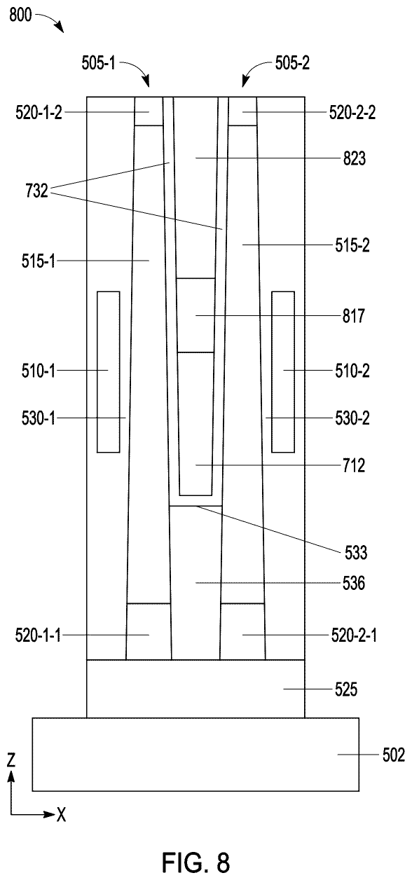

FIG. 8 is a cross-sectional view of a structure 800 after further processing structure 700 of FIG. 7. A material for a second conductive shield has been formed on conductive shield 712 in dielectric liner 732. The material for the second conductive shield has been recessed forming conductive shield 817 and opening 823. Conductive shield 817 can be a low work function material. Conductive shield 817 can be a metal, a metallic composition, or n+ polysilicon.

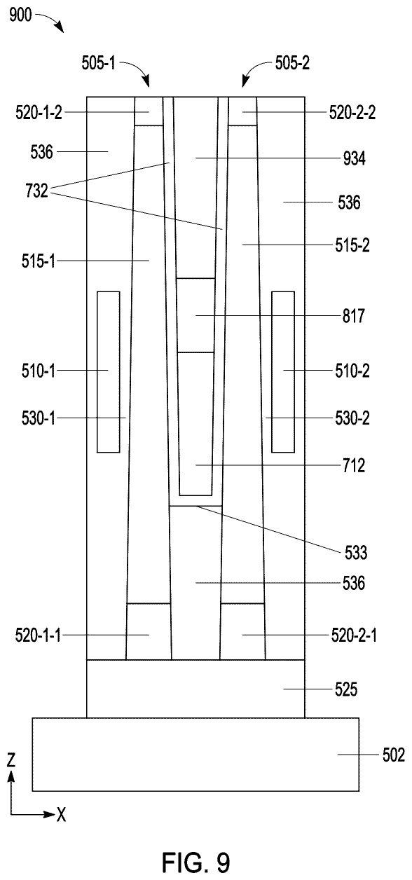

FIG. 9 is a cross-sectional view of a structure 900 after further processing structure 800 of FIG. 8. A dielectric 934 has been formed, filling opening 823 between walls of dielectric liner 732 and on a top surface of conductive shield 817. In the process flow, forming conductive shields in a liner process can be synergetic with a process of forming a single-gate TFT with no extra mask used. Since conductive shield 817 is formed on and contacting conductive shield 712, conductive shield 817 can be structured without a direct circuit contact, with electrical contact provided by a circuit contact to conductive shield 712. Alternatively, since conductive shield 817 is formed on and contacting conductive shield 712, conductive shield 712 can be structured without a direct circuit contact, with electrical contact provided by a circuit contact to conductive shield 817.

Various deposition techniques for components in the process flow of FIGS. 5-9 can be used that are typical for the material being formed, the dimensions of the material being formed, and the architecture in which the material is being formed in the fabrication flow. Material and structures can be formed by a suitable process such as, but not limited to, a deposition process including but not limited to physical vapor deposition (PVD), chemical vapor deposition (CVD), atomic layer depositon (ALD), or other deposition process. Other processes can be used. Selective etching can be used to remove selected regions in the processing discussed with respect to FIGS. 5-9. Selective etching is a process in which one or more materials are removed from a structure, while one or more other materials remain in the structure with no or little removal. Selective etching can depend on the material to be etched, the material not to be etched, the etchant employed, and the method for etching. Types of etching include wet etching and dry etching, where each of these two basic methods include a number of different etching procedures. In addition, conventional masking techniques, providing protective regions in the processing, can be used in removal of selected regions in forming the components of the memory device.

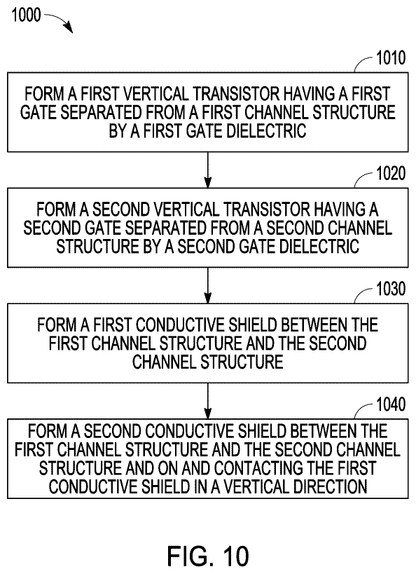

FIG. 10 is a flow diagram of an embodiment of an example method 1000 of forming an electronic device. At 1010, a first vertical transistor is formed having a first gate separated from a first channel structure by a first gate dielectric structure. At 1020, a second vertical transistor is formed having a second gate separated from a second channel structure by a second gate dielectric structure. The first vertical transistor and the second vertical transistor can be formed in a procedure that is common to forming both transistors. The first vertical transistor and the second vertical transistor can be formed as similar or identical transistors.

At 1030, a first conductive shield is formed between the first channel structure and the second channel structure. At 1040, a second conductive shield is formed between the first channel structure and the second channel structure and on and contacting the first conductive shield in a vertical direction. The second conductive shield has a material composition different from the material composition of the first conductive shield.

Variations of method 1000 or methods similar to method 1000 can include a number of different embodiments that may be combined depending on the application of such methods and/or the architecture of systems for which such methods are implemented. Variations can include forming the first conductive shield by forming a high work function material and forming the second conductive shield by forming a low work function material. The first conductive shield can have a metallic composition and the second conductive shield can have another metallic composition or a n-type polysilicon composition. The n-type polysilicon composition can have a relatively high conductivity associated with n+ type polysilicon.

Variations of method 1000 or methods similar to method 1000 can include performing a number of fabrication operations with the forming the first vertical transistor and the second vertical transistor. A dielectric liner can be formed in a trench between the first vertical transistor and the second vertical transistor, leaving an first opening in the dielectric liner. A bottom of the dielectric liner can end on a dielectric region above a conductive line on which the first vertical transistor and the second vertical transistor are formed. Material for the first conductive shield can be formed in the first opening in the dielectric liner and recessed for the first conductive shield, where the recessing operation leaves a second opening in the dielectric liner. Material for the second conductive shield is formed in the second opening and on and contacting the first conductive shield. The recessed material for the second conductive shield can leave a third opening in the dielectric liner. A dielectric fill can be formed in the third opening in the dielectric liner.

Variations of method 1000 or methods similar to method 1000 can include forming a third conductive shield on which the first conductive shield is formed, where the third conductive shield is a low work function material. The third conductive material can have the same composition as the second conductive material. Alternatively, the third conductive material can have a different composition from the second conductive material, where the first conductive material is a high work function material.

In various embodiments, a memory device can include data lines and access lines to an array of memory cells. The memory cells can be arranged having a first set of memory cells coupled to a first data line of the data lines and a second set of memory cells coupled to a second data line of the data lines. The first set can include a first vertical transistor having a first gate separated from a first channel structure by a first gate dielectric structure, where the first vertical transistor is coupled to and extends from a first data line of the data lines. The first set can include a second vertical transistor having a second gate separated from a second channel structure by a second gate dielectric structure, where the second vertical transistor also is coupled to and extends from the first data line. A first conductive shield can be structured between the first channel structure of the first vertical transistor and the second channel structure of the second vertical transistor. A second conductive shield can also be structured between the first channel structure of the first vertical transistor and the second channel structure of the second vertical transistor, where the second conductive shield contacts the first conductive shield in a vertical direction. The second conductive shield can have a material composition different from the first conductive shield. The access lines can include a first access line coupled to the first gate and a second access line coupled to the second gate, where the first access line is different from the second access line.

Variations of such a memory device and its features can include one or more features of embodiments of electronic devices as discussed herein. Variations of such a memory device and its features can include features as taught herein or permutations of features as taught herein. The first conductive shield between the first channel structure of the first vertical transistor and the second channel structure of the second vertical transistor can be a high work function material. The second conductive shield between the first channel structure of the first vertical transistor and the second channel structure of the second vertical transistor can be a low work function material. The first conductive shield can be a metal and the second conductive shield can be a metal, a metallic composition, or a n-type polysilicon composition. The first conductive shield and the second conductive shield can be positioned in a third dielectric structure, where the third dielectric structure has a first surface contacting the first channel structure and a second surface contacting the second channel structure.

Variations of such a memory device and its features can include the first vertical transistor coupled to a first capacitor and the second vertical transistor coupled to a second capacitor. Variations can include the first conductive shield positioned on and contacting a third conductive shield, where the third conductive shield is a low work function material.

Electronic devices have varying storage needs depending on, among other things, the type of electronic device, use environment, performance expectations, or other parameters in their operation. Such electronic devices can include, but are not limited to, mobile electronic devices, electronic devices for use in automotive applications, internet-connected appliances or devices, and combinations thereof. Mobile electronic devices with varying storage specifications can include smart phones, tablets, and other similar devices. Electronic devices for use in automotive applications, with varying storage specifications, can include one or more electronic components in automotive IVI systems, automotive sensors, automotive control units, automotive driver-assistance systems, automotive passenger safety systems, automotive comfort systems, and other similar automotive-directed systems. Electronic devices for use in internet-connected appliances or devices can include Internet-of-Things (IoT) devices and other similar systems.

Electronic devices can be broken down into several main components: one or more processors, one or more memory devices, storage devices, or other components. The one or more processors can include a central processing unit (CPU) and other main processing control unit. Memory devices can include one or more volatile or non-volatile RAM memory devices, such as DRAM devices, mobile or low-power double-data-rate synchronous DRAM (DDR SDRAM), and other similar devices. Storage devices can include non-volatile memory (NVM) devices, such as flash memory, ROM, a solid-state drive (SSD), a MultiMediaCard (MMC), other memory card structure or assembly, and other similar devices. In certain examples, electronic devices can include a user interface such as a display, a touch-screen, a keyboard, one or more buttons, and other interacting structures, a graphics processing unit (GPU), a power management circuit, a baseband processor, one or more transceiver circuits and other interacting devices. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

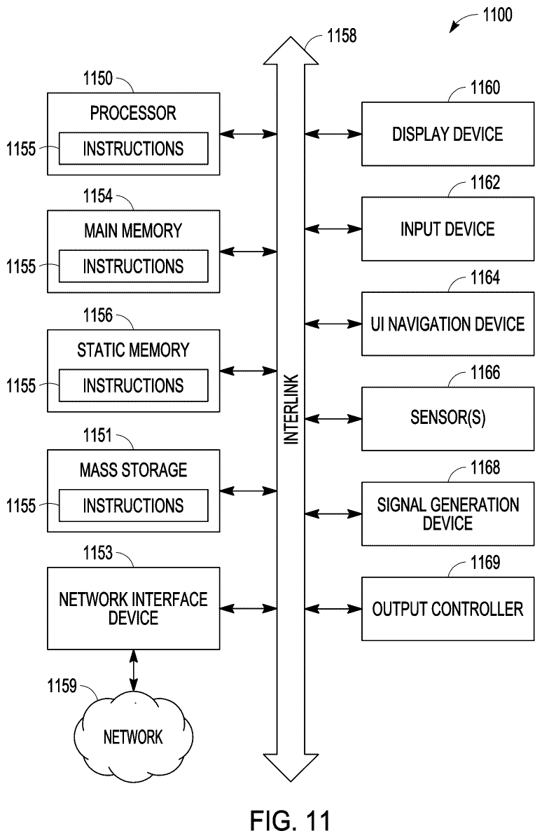

FIG. 11 illustrates a block diagram of an example machine 1100 having one or more embodiments of a machine that can be implemented with one or more devices having a pair of single-gate vertical transistors with multiple conductive shields between adjacent pairs of vertical transistors, as discussed herein. The multiple conductive shields can be a set of stacked conductive shields having a conductive shield of high work function material and a low work fuction material. In alternative embodiments, machine 1100 can operate as a standalone device or can be connected to other machines, for example in a network arrangement. In a networked deployment, machine 1100 can operate in the capacity of a server machine, a client machine, or both in server-client network environments. In an example, machine 1100 can act as a peer machine in peer-to-peer (P2P) network environment or other distributed arrangement. Machine 1100 can be a personal computer (PC), a tablet PC, a set-top box (STB), a personal digital assistant (PDA), a mobile telephone, a web appliance, an IoT device, an automotive system, or any machine capable of executing instructions (sequential or otherwise) that specify actions to be taken by that machine. Further, while only a single machine is illustrated, the term “machine” shall also be taken to include any collection of machines that individually or jointly execute a set, or multiple sets, of instructions to perform any one or more of the methodologies such as cloud computing, software as a service (SaaS), or other computer cluster configurations.

The machine 1100 can include a hardware processor 1150, a main memory 1154, and a static memory 1156, some or all of which can communicate with each other via an interlink 1158. Processor 1150 can be, but is not limited to, a CPU, a GPU, a hardware processor core, or any combination thereof. Interlink 1158 can include a bus. Machine 1100 can further include a display device 1160, an input device 1162, which can be an alphanumeric input device (for example, a keyboard), and a user interface (UI) navigation device 1164 (for example, a mouse). In an example, display device 1160, input device 1162, and UI navigation device 1164 can include a touch screen display. Machine 1100 can additionally include a mass storage device (for example, a drive unit) 1151, a network interface device 1153, a signal generation device 1168, and one or more sensors 1166, such as a global positioning system (GPS) sensor, compass, accelerometer, or other sensor. Machine 1100 can include an output controller 1169, such as a serial connection, a parallel connection, or other wired or wireless connection to communicate or control one or more peripheral devices. A serial connection can include a universal serial bus (USB) connector, Wireless connection can include infrared (IR) devices, near field communication (NFC) devices, and other communication devices. Peripheral devices can include a printer, card reader, or other similar device.

Machine 1100 can include one or more machine-readable media on which is stored one or more sets of data structures or instructions 1155 embodying or utilized by machine 1100 to perform any one or more of the techniques or functions for which machine 1100 is designed. Instructions 1155 can include, but are not limited to, software, an operating system (OS), microcode, or other type of instructions. Instructions 1155 can reside, completely or at least partially, within main memory 1154, within static memory 1156, or within hardware processor 1150 during execution thereof by machine 1100. In an example, one or any combination of hardware processor 1150, main memory 1154, static memory 1156, or mass storage device 1151 can constitute the machine-readable media on which is stored one or more sets of data structures or instructions. Various ones of hardware processor 1150, main memory 1154, static memory 1156, or mass storage device 1151 can include one or more devices having a pair of single-gate vertical transistors with multiple conductive shields between adjacent pairs of vertical transistors, as discussed herein. The multiple conductive shields can be a set of stacked conductive shields having a conductive shield of high work function material and a low work fuction material, as discussed herein.

While an example machine-readable medium is illustrated as a single medium, the term “machine-readable medium” can include a single medium or multiple media configured to store instructions 1155 or data. Examples of single medium or multiple media can include a centralized or distributed database, centralized or distributed memory devices, or associated caches and servers, or other similar devices or systems. The term “machine-readable medium” can include any medium that is capable of storing instructions for execution by machine 1100 and that cause machine 1100 to perform any one or more of the techniques to which machine 1100 is designed, or that is capable of storing data structures used by or associated with such instructions. Non-limiting machine-readable medium examples can include solid-state memories, optical media, and magnetic media. Specific examples of non-transitory machine-readable media can include: non-volatile memory, such as semiconductor memory devices (e.g., EPROM, EEPROM) and flash memory devices; magnetic disks, such as internal hard disks and removable disks; magneto-optical disks; and compact disc-ROM (CD-ROM) and digital versatile disc-read only memory (DVD-ROM) disks.

Instructions 1155 or other data stored on mass storage device 1151 can be accessed by main memory 1154 for use by hardware processor 1150. Main memory 1154, which may include a DRAM, is typically fast, but volatile, and thus a different type of storage than mass storage device 1151, for example a SSD, which is suitable for long-term storage, including while in an “off” condition. Instructions 1155 or data in use by a user or machine 1100 are typically loaded in main memory 1154 for use by hardware processor 1150. When main memory 1154 is full, virtual space from mass storage device 1151 can be allocated to supplement main memory 1154; however, because mass storage device 1151 is typically slower than main memory 1154, and write speeds are typically at least twice as slow as read speeds, use of virtual memory can greatly reduce user experience due to storage device latency, in contrast to main memory 1154. Further, use of mass storage device 1151 for virtual memory can greatly reduce the usable lifespan of mass storage device 1151.

Storage devices optimized for mobile electronic devices, or mobile storage, traditionally include MMC solid-state storage devices, for example micro Secure Digital (microSD™) cards. MMC devices include a number of parallel interfaces, for example an 8-bit parallel interface, with a host device and are often removable and separate components from the host device. In contrast, embedded MMC (eMMC™) devices are attached to a circuit board and considered a component of the host device, with read speeds that rival Serial Advanced Technology Attachment (SATA)-based SSD devices. However, demand for mobile device performance continues to increase, such as to fully enable virtual or augmented-reality devices or utilize increasing networks speeds, among other things. In response to this demand, storage devices have shifted from parallel to serial communication interfaces. Universal Flash Storage (UFS) devices, including controllers and firmware, communicate with a host device using a low-voltage differential signaling (LVDS) serial interface with dedicated read/write paths, further advancing greater read/write speeds.

Instructions 1155 can further be transmitted or received over a network 1159 using a transmission medium via signal generation device 1168 or network interface device 1153 utilizing any one of a number of transfer protocols. Examples of transfer protocols include, but are not limited to, frame relay, Internet protocol (IP), transmission control protocol (TCP), user datagram protocol (UDP), hypertext transfer protocol (HTTP), and other appropriate protocols. Example communication networks can include a local area network (LAN), a wide area network (WAN), a packet data network, for example the Internet), mobile telephone networks, Plain Old Telephone (POTS) networks, and wireless data networks, P2P networks, among others. Wireless data networks can include, but are not limited to, Institute of Electrical and Electronics Engineers (IEEE) 802.11 family of standards known as Wi-Fi®, IEEE 802.16 family of standards known as WiMax®), and IEEE 802.15.4 family of standards. In an example, signal generation device 1168 or network interface device 1153 can include one or more physical jacks or one or more antennas to connect to network 1159. The physical jacks can include, for example Ethernet, coaxial, or phone jacks. In an example, signal generation device 1168 or network interface device 1153 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of carrying instructions to and for execution by machine 1100 or data to or from machine 1100, and can include instrumentalities to propagate digital or analog communications signals to facilitate communication of such instructions, which instructions may be implemented as software or data.

The following example embodiments of devices, systems, and methods, in accordance with the teachings herein.

An example electronic device 1 can comprise: a first vertical transistor having a first gate separated from a first channel structure by a first gate dielectric structure; a second vertical transistor having a second gate separated from a second channel structure by a second gate dielectric structure; a first conductive shield between the first channel structure and the second channel structure; and a second conductive shield between the first channel structure and the second channel structure, the second conductive shield contacting the first conductive shield in a vertical direction, the second conductive shield having a material composition different from the first conductive shield.

An example electronic device 2 can include features of example electronic device 1 and can include the first conductive shield being a high work function material and the second conductive shield being a low work function material.

An example electronic device 3 can include features of example electronic device 2 and any of the preceding example electronic devices and can include the first conductive shield having a first metallic composition and the second conductive shield having a second metallic composition or a n-type polysilicon composition.

An example electronic device 4 can include features of any of the preceding example electronic devices and can include the first conductive shield and the second conductive shield positioned in a third dielectric structure, the third dielectric structure having a first surface contacting the first channel structure and a second surface contacting the second channel structure.

An example electronic device 5 can include features of example electronic device 4 and any of the preceding example electronic devices and can include the first conductive shield being on and contacting a lower horizontal surface of the third dielectric structure.

An example electronic device 6 can include features of example electronic device 5 and any of the preceding example electronic devices and can include the lower horizontal surface being above a conductive region.

An example electronic device 7 can include features of example electronic device 4 and any of the preceding example memory devices and can include a dielectric region being on and contacting the second conductive shield and being between the first surface and the second surface of the third dielectric structure.

An example electronic device 8 can include features of example electronic device 7 and any of the preceding example electronic devices and can include the third dielectric structure and the dielectric region having a common composition.

An example electronic device 9 can include features of any of the preceding example electronic devices and can include the first conductive shield being on and contacting a third conductive shield, the third conductive shield having a material composition different from the first conductive shield.

In an example electronic device 10, any of the electronic devices of example electronic devices 1 to 9 may include electronic devices incorporated into an electronic apparatus further comprising a host processor and a communication bus extending between the host processor and the electronic device.

In an example electronic device 11, any of the electronic devices of example electronic devices 1 to 10 may be modified to include any structure presented in another of example electronic device 1 to 10.

In an example electronic device 12, any apparatus associated with the electronic devices of example electronic devices 1 to 11 may further include a machine-readable storage device configured to store instructions as a physical state, wherein the instructions may be used to perform one or more operations of the apparatus.

In an example electronic device 13, any of the electronic devices of example electronic devices 1 to 12 may be operated in accordance with any of the below example methods 1 to 9.

An example memory device 1 can comprise: data lines; an array of memory cells, the memory cells arranged having a first set of memory cells coupled to a first data line of the data lines and a second set of memory cells coupled to a second data line of the data lines, the first set including: a first vertical transistor having a first gate separated from a first channel structure by a first gate dielectric structure, the first vertical transistor coupled to and extending from a first data line of the data lines; a second vertical transistor having a second gate separated from a second channel structure by a second gate dielectric structure, the second vertical transistor coupled to and extending from the first data line; a first conductive shield between the first channel structure and the second channel structure; and a second conductive shield between the first channel structure and the second channel structure, the second conductive shield contacting the first conductive shield in a vertical direction, the second conductive shield having a material composition different from the first conductive shield; and access lines including a first access line coupled to the first gate and a second access line coupled to the second gate, the first access line being different from the second access line.

An example memory device 2 can include features of example memory device 1 and can include the first conductive shield being a high work function material and the second conductive shield being a low work function material.

An example memory device 3 can include features of example memory device 2 and any of the preceding example memory devices and can include the first conductive shield being a metal and the second conductive shield being a metal or a n-type polysilicon composition.

An example memory device 4 can include features of any of the preceding example memory devices and can include the first conductive shield and the second conductive shield positioned in a third dielectric structure, the third dielectric structure having a first surface contacting the first channel structure and a second surface contacting the second channel structure.

An example memory device 5 can include features of any of the preceding example memory devices and can include the first conductive shield being on and contacting a third conductive shield, the third conductive being a low work function material.

An example memory device 6 can include features of any of the preceding example memory devices and can include the first vertical transistor being coupled to a first capacitor and the second vertical transistor being coupled to a second capacitor.

In an example memory device 7, any of the preceding example memory devices may include memory devices incorporated into an electronic apparatus further comprising a host processor and a communication bus extending between the host processor and the memory device.

In an example memory device 8, any of the example memory devices 1 to 7 may be modified to include any structure presented in another of example memory device 1 to 7.

In an example memory device 9, any apparatus associated with the example memory devices 1 to 8 may further include a machine-readable storage device configured to store instructions as a physical state, wherein the instructions may be used to perform one or more operations of the apparatus.

In an example memory device 10, any of the example memory devices 1 to 9 may be operated in accordance with any of the below example methods 1 to 9.

An example method 1 can comprise forming a first vertical transistor having a first gate separated from a first channel structure by a first gate dielectric structure; forming a second vertical transistor having a second gate separated from a second channel structure by a second gate dielectric structure; forming a first conductive shield between the first channel structure and the second channel structure; and forming a second conductive shield between the first channel structure and the second channel structure and on and contacting the first conductive shield in a vertical direction, the second conductive shield having a material composition different from the first conductive shield.

An example method 2 can include features of example method 1 and can include forming the first conductive shield to include forming a high work function material and forming the second conductive shield to include forming a low work function material.

An example method 3 can include features of example method 2 and any of the preceding example methods and can include the first conductive shield having a first metallic composition and the second conductive shield having a second metallic composition or a n-type polysilicon composition.

An example method 4 can include features of any of the preceding example methods and can include, with forming the first vertical transistor and the second vertical transistor: forming a dielectric liner in a trench between the first vertical transistor and the second vertical transistor, leaving an first opening in the dielectric liner, a bottom of the dielectric liner ending on a dielectric region above a conductive line on which the first vertical transistor and the second vertical transistor are formed; forming material for the first conductive shield in the first opening in the dielectric liner and recessing the material for the first conductive shield, leaving a second opening in the dielectric liner; forming material for the second conductive shield in the second opening and on and contacting the first conductive shield and recessing the material for the second conductive shield leaving a third opening in the dielectric liner; and forming dielectric fill in the third opening in the dielectric liner.

An example method 5 can include features of any of the preceding example methods and can include forming a third conductive shield on which the first conductive shield is formed, the third conductive shield being a low work function material.

In an example method 6, any of the example methods 1 to 5 may be performed in forming an electronic apparatus further comprising a host processor and a communication bus extending between the host processor and the memory system.

In an example method 7, any of the example methods 1 to 6 may be modified to include operations set forth in any other of example methods 1 to 6.

In an example method 8, any of the example methods 1 to 7 may be implemented at least in part through use of instructions stored as a physical state in one or more machine-readable storage devices.

An example method 9 can include features of any of the preceding example methods 1 to 8 and can include performing functions associated with any features of example electronic systems 1 to 13 and any features of example memory devices 1 to 10.

An example machine-readable storage device storing instructions, that when executed by one or more processors, cause a machine to perform operations, can comprise instructions to perform functions associated with any features of example electronic systems 1 to 13 and example memory devices 1 to 10, or perform methods associated with any features of example methods 1 to 9.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. An electronic device comprising:
a first vertical transistor having a first gate separated from a first channel structure by a first gate dielectric structure;
a second vertical transistor having a second gate separated from a second channel structure by a second gate dielectric;
a first conductive shield between the first channel structure and the second channel structure; and
a second conductive shield between the first channel structure and the second channel structure, the second conductive shield contacting the first conductive shield in a vertical direction, the second conductive shield having a material composition different from the first conductive shield.

2. The electronic device of claim 1, wherein the first conductive shield is a high work function material and the second conductive shield is a low work function material.

3. The electronic device of claim 2, wherein the first conductive shield has a first metallic composition and the second conductive shield has a second metallic composition or a n-type polysilicon composition.

4. The electronic device of claim 1, wherein the first conductive shield and the second conductive shield are positioned in a third dielectric structure, the third dielectric structure having a first surface contacting the first channel structure and a second surface contacting the second channel structure.

5. The electronic device of claim 4, wherein the first conductive shield is on and contacting a lower horizontal surface of the third dielectric structure.

6. The electronic device of claim 5, wherein the lower horizontal surface is above a conductive region.

7. The electronic device of claim 4, wherein a dielectric region is on and contacting the second conductive shield and is between the first surface and the second surface of the third dielectric structure.

8. The electronic device of claim 7, wherein the third dielectric structure and the dielectric region have a common composition.

9. The electronic device of claim 1, wherein the first conductive shield is on and contacting a third conductive shield, the third conductive shield having a material composition different from the first conductive shield.

10. A memory device comprising:
data lines;
an array of memory cells, the memory cells arranged having a first set of memory cells coupled to a first data line of the data lines and a second set of memory cells coupled to a second data line of the data lines, the first set including:
a first vertical transistor having a first gate separated from a first channel structure by a first gate dielectric structure, the first vertical transistor coupled to and extending from a first data line of the data lines;
a second vertical transistor having a second gate separated from a second channel structure by a second gate dielectric structure, the second vertical transistor coupled to and extending from the first data line;
a first conductive shield between the first channel structure and the second channel structure; and
a second conductive shield between the first channel structure and the second channel structure, the second conductive shield contacting the first conductive shield in a vertical direction, the second conductive shield having a material composition different from the first conductive shield; and
access lines including a first access line coupled to the first gate and a second access line coupled to the second gate, the first access line being different from the second access line.

11. The memory device of claim 10, wherein the first conductive shield is a high work function material and the second conductive shield is a low work function material.

12. The memory device of claim 11, wherein the first conductive shield is a metal and the second conductive shield is a metal or a n-type polysilicon composition.

13. The memory device of claim 10, wherein the first conductive shield and the second conductive shield are positioned in a third dielectric structure, the third dielectric structure having a first surface contacting the first channel structure and a second surface contacting the second channel structure.

14. The memory device of claim 10, wherein the first conductive shield is on and contacting a third conductive shield, the third conductive being a low work function material.

15. The memory device of claim 10, wherein the first vertical transistor is coupled to a first capacitor and the second vertical transistor is coupled to a second capacitor.

16. A method comprising:
forming a first vertical transistor having a first gate separated from a first channel structure by a first gate dielectric structure;
forming a second vertical transistor having a second gate separated from a second channel structure by a second gate dielectric structure;
forming a first conductive shield between the first channel structure and the second channel structure; and
forming a second conductive shield between the first channel structure and the second channel structure and on and contacting the first conductive shield in a vertical direction, the second conductive shield having a material composition different from the first conductive shield.

17. The method of claim 16, wherein forming the first conductive shield includes forming a high work function material and forming the second conductive shield includes forming a low work function material.

18. The method of claim 17, wherein the first conductive shield has a first metallic composition and the second conductive shield has a second metallic composition or a n-type polysilicon composition.

19. The method of claim 16, wherein the method includes, with forming the first vertical transistor and the second vertical transistor:
forming a dielectric liner in a trench between the first vertical transistor and the second vertical transistor, leaving an first opening in the dielectric liner, a bottom of the dielectric liner ending on a dielectric region above a conductive line on which the first vertical transistor and the second vertical transistor are formed;
forming material for the first conductive shield in the first opening in the dielectric liner and recessing the material for the first conductive shield, leaving a second opening in the dielectric liner;
forming material for the second conductive shield in the second opening and on and contacting the first conductive shield and recessing the material for the second conductive shield leaving a third opening in the dielectric liner; and
forming dielectric fill in the third opening in the dielectric liner.

20. The method of claim 16, wherein the method includes forming a third conductive shield on which the first conductive shield is formed, the third conductive shield being a low work function material.
